(19) United States
(12) Patent Application Publication
(10) Pub. No.: US 2016/0118155 A1
(43) Pub. Date: Apr. 28, 2016

(54) CONDUCTIVE PASTE, METHOD OF PRODUCING CONDUCTIVE PATTERN, AND TOUCH PANEL

(71) Applicant: TORAY INDUSTRIES, INC., Tokyo (JP)

(72) Inventor: Yasuhiro Kobayashi, Otsu-shi (JP)

(21) Appl. No.: 14/890,456

(22) PCT Filed: Jun. 19, 2014
(86) PCT No.: PCT/JP2014/066280

§ 371 Date: Nov. 11, 2015

(30) Foreign Application Priority Data
Jun. 27, 2013 (JP) 2013-134667

(51) Int. Cl. H01B 1/20; H03K 17/96

(52) U.S. Cl. CPC H01B 1/20; H03K 17/962

(57) ABSTRACT

A conductive paste includes a conductive filler (A), a zwitterionic compound (B) and a thermosetting compound (C); a method of producing a conductive pattern including applying the conductive paste to obtain a coating film, drying the coating film to obtain a dried film, exposing and developing the dried film to obtain a pattern, and curing the pattern at 100 to 200° C. to obtain a conductive pattern; and an electrostatic capacitance type touch panel including as peripheral wiring the conductive pattern produced by the method of producing the conductive pattern.

### TECHNICAL FIELD

This disclosure relates to a conductive paste, a method of producing a conductive pattern, and a touch panel.

### BACKGROUND

In recent years, mobile electronic devices such as smartphones and tablet PCs have been extensively developed. Displays and touch panels, i.e., members of mobile electronic devices, are required to have a reduced size and improved definition.

As a method of forming a conductive pattern on a substrate of a display, a touch panel or the like, a vapor deposition method is known. The vapor deposition method is capable of forming a high-definition pattern of 20 μm or less. However, the vapor deposition method has the problem of rising costs due to investments in plant and equipment and complicated processes.

To form conductive patterns at lower costs, a material that forms an organic-inorganic composite conductive pattern has been put into practical use, the material containing a resin as an organic component and a conductive filler as an inorganic component. Specifically, so-called a polymer-type conductive paste with a large amount of silver powder, copper powder or carbon powder mixed as a conductive filler in a resin or an adhesive containing a resin has been put into practical use.

For many of the conductive pastes, a conductive pattern can be obtained by heating and curing a pattern formed by a screen printing method (Japanese Patent Laid-open Publication No. 2012-18783 and Japanese Patent Laid-open Publication No. 2007-207567). However, it is difficult to accurately form a conductive pattern of 100 μm or less.

Thus, a conductive paste capable of being acidic-etched (Japanese Patent Laid-open Publication No. 10-64333) and photosensitive curable conductive pastes (Japanese Patent Laid-open Publication No. 2003-162921, International Publication No. WO 2004/61006 and Japanese Patent Laid-open Publication No. 2013-101861) have been developed.

However, for the conductive paste described in JP '333, which is capable of being acidic-etched, it is necessary to form a resist layer in formation of a conductive pattern. Accordingly, there is the problem that the production process is complicated.

The conventional photosensitive curable conductive pastes described in JP '921, WO '006 and JP '861 have the problem that the resulting conductive pattern has low conductivity, and the resulting conductive pattern is fragile, or poor in adhesion to a substrate or the like.

Further, it is increasingly required to use a substrate formed of a polymer. Since a substrate formed of a polymer is poor in heat resistance, exhibition of conductivity under lower-temperature curing conditions is required.

Thus, it could be helpful to provide a conductive paste capable of forming a fine conductive pattern that has remarkably high adhesion and exhibits conductivity under relatively low-temperature curing conditions.

### SUMMARY

I thus provide:
(1) A conductive paste including a conductive filler (A), a zwitterionic compound (B) and a thermosetting compound (C).
(2) The conductive paste according to (1), wherein the ratio of the zwitterionic compound (B) to the conductive filler (A) is 0.05 to 5% by weight.
(3) The conductive paste according to (1) or (2), further including a photopolymerization initiator (D), and a compound (E) having a carboxyl group and/or a compound (F) having a carbon-carbon double bond.
(4) The conductive paste according to (3), wherein the compound (E) having a carboxyl group is an acryl-based copolymer containing an epoxy acrylate or an epoxy methacrylate as an acryl-based monomer having a carbon-carbon double bond.
(5) The conductive paste according to any one of (1) to (4), wherein the zwitterionic compound (B) is a compound selected from the group consisting of an amino acid, a compound represented by Formula (1) and a compound represented by Formula (2):

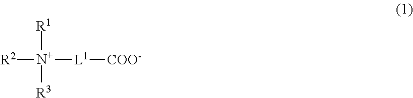

wherein R¹, R² and R³ each independently represent an organic group, and L¹ represents a divalent linking group, where R³ and R² or L¹ may be linked with each other to form a ring, and the ring may have a substituent; and

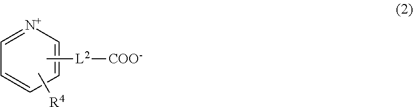

wherein R⁴ represents an alkyl group with a carbon number of 1 to 6 or a hydrogen atom, which is bonded at any one of the 1 to 6-positions of a pyridinium ring, and L² represents a divalent linking group bonded at any one of the 1 to 6-positions of the pyridinium ring, where R⁴ or L² is bonded at the 1-position of the pyridinium ring.
(6) The conductive paste according to (5), wherein R¹, R² and R³ each independently represent an alkyl group with a carbon number of 1 to 6.
(7) A method of producing a conductive pattern, the method including: a coating step of applying the conductive paste according to any one of (1) to (6) to obtain a coating film; a drying step of drying the coating film to obtain a dried film; a pattern forming step of exposing and developing the dried film to obtain a pattern; and a curing step of curing the pattern at 100 to 200° C. to obtain a conductive pattern.
(8) An electrostatic capacitance type touch panel including as peripheral wiring the conductive pattern produced by the method of producing a conductive pattern according to (7).

According to the conductive paste, not only a fine conductive pattern excellent in adhesion is obtained, but also a conductive pattern having a low resistivity can be obtained under low curing temperature conditions.

### BRIEF DESCRIPTION OF THE DRAWING

FIG. 1 is a schematic view showing a light transmission pattern of a photomask used for evaluation of a resistivity in examples.

### DESCRIPTION OF REFERENCE SIGNS

A: Light transmission part

### DETAILED DESCRIPTION

My conductive paste includes a conductive filler (A), a zwitterionic compound (B) and a thermosetting compound (C). A conductive pattern that forms electrode wiring can be formed by a method such as a screen printing method or a photosensitive method (photolithography method) using the conductive paste.

Examples of the conductive filler (A) contained in the conductive paste include particles of Ag, Au, Cu, Pt, Pb, Sn, Ni, Al, W, Mo, ruthenium oxide, Cr, Ti, carbon and indium. Particles of a combination of these materials can also be used. A mixture of these particles can also be used. Particles of Ag, Cu or Au are preferred from the viewpoint of conductivity, and particles of Ag are more preferred from the viewpoint of costs and stability.

The median diameter (D50) of the conductive filler (A) is preferably not less than 0.1 μm and not more than 10 μm, more preferably not less than 0.5 μm and not more than 6 μm. When the median diameter D50 is 0.1 μm or more, the contact probability between conductive fillers (A) in the curing step increases, and the resistivity and the breakage probability of the produced conductive pattern decrease. Further, in the exposure step, exposure light can smoothly pass through a coating film obtained by applying the conductive paste so that fine patterning is facilitated. On the other hand, when the median diameter D50 is 10 μm or less, the surface smoothness, pattern accuracy, and dimensional accuracy of the produced conductive pattern are improved. The median diameter D50 can be measured by a laser light scattering method.

The ratio of the conductive filler (A) to the total solid content in the conductive paste is preferably not less than 60% by weight and not more than 95% by weight, more preferably not less than 70% by weight and not more than 90% by weight based on the total solid content in the conductive paste. When the added amount of the conductive filler (A) is 60% by weight or more based on the total solid content, the contact probability between conductive fillers (A) in the curing step increases, and the resistivity and the breakage probability of the produced conductive pattern decrease. On the other hand, when the added amount of the conductive filler (A) is 95% by weight or less based on the total solid content, in the exposure step, exposure light can smoothly pass through a coating film obtained by applying the conductive paste so that fine patterning is facilitated. The total solid content refers to all constituents of the conductive paste excluding the solvent.

The ratio of the conductive filler (A) to the total solid content in the conductive paste can be controlled of the added amounts of the conductive filler (A) and the zwitterionic compound (B) and an organic component such as the thermosetting compound (C) during preparation of the conductive paste. The ratio of the conductive filler (A) to the total solid content can be measured by thermogravimetric analysis (hereinafter, referred to as “TGA”). More specifically, using about 10 mg of the conductive paste, a change in weight with the temperature elevated from 25° C. to 600° C. can be measured by TGA (e.g., TGA-50 manufactured by Shimadzu Corporation). Usually, the solvent in the conductive paste is evaporated at 100 to 150° C., and therefore the sample weight at the time when the temperature reaches 150° C. is equivalent to the weight of the total solid content. The sample weight at the time when the temperature reaches 600° C. is roughly equivalent to the weight of the conductive filler (A) because the zwitterionic compound (B), the thermosetting compound (C) and so on have been removed. Accordingly, the ratio of the conductive filler (A) to the total solid content is determined from the ratio of the sample weight at the time when the temperature reaches 600° C. to the sample weight at the time when the temperature reaches 150° C. When the conductive pattern is used as a sample, pieces taken by scraping off the conductive paste can be measured by TGA in the same manner as in the paste.

The zwitterionic compound (B) contained in the conductive paste (hereinafter, referred to as “compound B”) refers to a compound having both a positive charge and a negative charge in one molecule. When the conductive paste contains the compound (B), a conductive pattern having a low resistivity can be obtained even under low-temperature curing conditions although a detailed mechanism thereof is not known.

Examples of the compound (B) include low-molecular-weight betaines having a quaternary ammonium cation and a carboxylate anion such as carnitine, acetylcarnitine, N,N,N-trimethylglycine (also called glycinebetaine), N,N,N-triethylglycine, N,N,N-tripropylglycine, N,N,N-triisopropylglycine, N,N,N-trimethyl-γ-aminobutyric acid, N,N,N-trimethylalanine, N,N,N-triethylalanine, N,N,N-triisopropylalanine, N,N,N-trimethyl-2-methylalanine, N,N,N-trimethylammoniopropionate and proline betaine.

Examples of the compound (B) also include amphoteric surfactants having a quaternary ammonium cation and a carboxylate anion such as lauryl betaine (e.g., AMPHITOL 24B (effective component: 26% by weight; manufactured by Kao Corporation)), stearyl betaine, laurylic acid amide propyl betaine, coconut oil fatty acid amide propyl betaine, octanoic acid amide propyl betaine and 2-alkyl-N-carboxymethyl-N-hydroxyethylimidazolinium betaine (e.g., AMPHITOL 20YB (effective component: 40% by weight; manufactured by Kao Corporation)).

Examples of the compound (B) also include polymers having a quaternary ammonium cation and a carboxylate anion on the side chain such as YUKAFORMER (registered trademark) AMPHOSET, YUKAFORMER (registered trademark) 104D, YUKAFORMER (registered trademark) 301 and YUKAFORMER (registered trademark) SM (each manufactured by Mitsubishi Chemical Corporation), and RAM RESIN-1000, RAM Resin-2000, RAM RESIN-3000 and RAM RESIN-4000 (each manufactured by OSAKA ORGANIC CHEMICAL INDUSTRY LTD.).

Examples of the compound (B) also include compounds having a pyridinium cation and a carboxylate anion such as pyridinoacetate, pyridinopropionate and trigonelline.

Examples of the compound (B) also include compounds having a quaternary ammonium cation and a sulfonate anion such as octadecyldimethyl(3-sulfopropyl)ammonium hydroxide intramolecular salts, dodecyldimethyl(3-sulfopropyl)ammonium hydroxide intramolecular salts, stearyl sulfobetaine, palmityl sulfobetaine, myristyl sulfobetaine, lauryl sulfobetaine, cocamidopropyl hydroxysultaine, 3-(ethyldimethylammonio)propane-1-sulfonate and 3-(benzyldimethylammonio)propane-1-sulfonate.

Examples of the compound (B) also include compounds having a pyridinium cation and a sulfonate anion such as 1-(3-sulfopropyl)pyridinium hydroxide intramolecular salts.

Examples of the compound (B) also include compounds having a quaternary ammonium cation and a phosphate anion such as phosphatidylcholine and lecithin.

Examples of the compound (B) also include amine oxide type compounds such as lauryldimethylamine N-oxide, oleyldimethylamine N-oxide, nicotinic acid N-oxide, 2-methylpyridine N-oxide, trimethylamine N-oxide and pyridine N-oxide.

Examples of the compound (B) also include amino acids such as alanine, arginine, as-paragine, aspartic acid, cysteine, glutamine, glutamic acid, glycine, histidine, isoleucine, leucine, lysine, methionine, phenylalanine, proline, serine, threonine, tryptophan, tyrosine, valine, N-methylglycine, β-alanine, ornithine, creatine, γ-amino butyric acid, theanine and kainic acid.

The compound (B) is preferably an amino acid, or a compound having a structure of Formula (1) or (2):

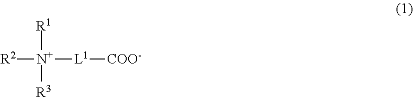

wherein R¹, R² and R³ each independently represent an organic group, and L¹ represents a divalent linking group, where R³ and R² or L¹ may be linked with each other to form a ring, and the ring may have a substituent.

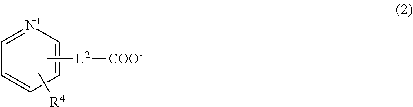

wherein R⁴ represents an alkyl group with a carbon number of 1 to 6 or a hydrogen atom, which is bonded at any one of the 1 to 6-positions of a pyridinium ring, and L² represents a divalent linking group bonded at any one of the 1 to 6-positions of the pyridinium ring, where R⁴ or L² is bonded at the 1-position of the pyridinium ring.

Preferably, R¹, R² and R³ each independently represent an alkyl group with a carbon number of 1 to 6. Examples of the compound having a structure of Formula (1) or (2) where each of R¹, R² and R³ is an alkyl group with a carbon number of 1 to 6 include carnitine, acetylcarnitine, N,N,N-trimethylglycine, N,N,N-triethylglycine, N,N,N-tripropylglycine, N,N,N-triisopropylglycine, N,N,N-trimethyl-γ-aminobutyric acid, N,N,N-trimethylalanine, N,N,N-triethylalanine, N,N,N-triisopropylalanine, N,N,N-trimethyl-2-methylalanine and N,N,N-trimethylammoniopropionate. Carnitine and N,N,N-trimethylglycine are more preferred.

Examples of the divalent linking group include hydrocarbon groups such as an alkylene group, an alkenylene group, an alkynylene group and an arylene group; divalent linking groups derived from a compound having an aromatic heterocyclic ring (heteroaromatic compound) such as a thiophene-2,5-diyl group and a pyrazine-2,3-diyl group; divalent linking groups derived from a chalcogen atom such as O or S; and groups that are linked via a heteroatom such as an alkylimino group, a dialkylsilanediyl group and a diarylgermanediyl group. The alkylene group may have a substituent such as a hydroxyl group or an alkyl group. The alkylene group is preferably a methylene group, an ethylene group, a trimethylene group or a tetramethylene group.

The ratio of the compound (B) to the conductive filler (A) is preferably not less than 0.05% by weight and not more than 5% by weight, more preferably not less than 0.1% by weight and not more than 2% by weight. When the ratio of the compound (B) is 0.05% by weight or more, a conductive pattern having a low resistivity is obtained under low-temperature curing conditions. On the other hand, when the ratio of the compound (B) is 5% by weight or less, development resistance during patterning is sufficient so that a fine pattern can be formed.

The ratio of the compound (B) to the conductive filler (A) can be determined by quantitatively analyzing the content of each of the conductive filler (A) and the compound (B) in the paste by analysis of all components in the conductive paste.

The method of analyzing all components in the conductive paste is as follows:
(i) The conductive paste is diluted with an organic solvent, and subjected to ¹H-NMR measurement, GC measurement and GC/MS measurement to take an overview thereof
(ii) The conductive paste is extracted with an organic solvent, and then centrifugally separated into a soluble part and an insoluble part.
(iii) The insoluble part is extracted with a high-polarity organic solvent, and then centrifugally separated into a soluble part and an insoluble part.
(iv) A mixed liquid of the soluble parts obtained in (ii) and (iii) is subjected to IR measurement, ¹H-NMR measurement and GC/MS measurement. Further, the mixed liquid is fractionated by GPC. The resulting fractions are subjected to IR measurement and ¹H-NMR measurement. The fractions are subjected to GC measurement, GC/MS measurement, pyrolytic GC/MS measurement and MALDI/MS measurement as necessary.
(v) The insoluble part obtained in (iii) is subjected to IR measurement or TOF-SIMS measurement. When existence of an organic substance is confirmed, pyrolytic GC/MS or TPD/MS measurement is performed.
(vi) By comprehensively assessing the results of measurements in (i), (iv) and (v), the content of each of the components contained in the conductive paste can be determined. The high-polarity organic solvent to be used in (iii) is preferably chloroform, methanol or the like.

The compound (B) may be contained in the conductive paste while covering the conductive filler (A). As a surface treatment for covering the conductive filler (A) with the compound (B), a known method such as a wet treatment or a dry treatment can be used.

By the thermosetting compound (C) (hereinafter, referred to as “compound (C)”) contained in the conductive paste, adhesion of the conductive paste to the substrate can be enhanced, or the coating film can be strengthened. Examples of the thermosetting compound (C) include epoxy compounds, oxetane compounds, isocyanate compounds and alkoxy compounds.

Examples of the epoxy compound include epoxy resins and phenoxy resins such as those of bisphenol A type, hydrogenated bisphenol A type, bisphenol F type, bisphenol S type, phenol novolac type, cresol novolac type, bisphenol A novolac type, biphenol type, bixylenol type, trisphenolmethane type, glycidylamine type and glycidyl ester type.

Examples of the epoxy compound also include α-triglycidyl isocyanurate, β-triglycidyl isocyanurate, cycloaliphatic epoxy resins, cycloaliphatic phenoxy resins, heterocyclic epoxy resins and heterocyclic phenoxy resins.

Examples of the epoxy compound include jER (registered trademark) 828, ADEKA RESIN EPR-21, ADEKA RESIN EPR-4030, jER (registered trademark) 1001, jER (registered trademark) 1002 and jER (registered trademark) 1256.

The epoxy equivalent of the epoxy compound is preferably 200 to 500 g/equivalent. When the epoxy equivalent is 200 to 500 g/equivalent, a conductive pattern with high adhesion to various kinds of substrates such as resin films and glass substrates can be obtained. The epoxy equivalent refers to a weight of a resin containing 1 equivalent of epoxy groups, and can be determined in the following manner: a molecular weight determined from a structural formula is divided by the number of epoxy groups contained in the structure.

Examples of the oxetane compound include 3-ethyl-3-hydroxymethyloxetane (e.g., ARON OXETANE (registered trademark) OXT-101 manufactured by Toagosei Company, Limited), 2-ethylhexyloxetane, xylylene-bis-oxetane, 3-ethyl-{[3-ethyloxetane-3-yl)methoxy]methyl}oxetane, 3-ethyl-3-(phenoxymethyl)oxetane, 3-ethyl-3-(2-ethylhexyloxymethyl)oxetane, 1,4-bis{[(3-ethyl-3-oxetanyl)methoxy]methy}benzene, bis(3-ethyl-3-oxetanylmethyl)ether and novolac type oxetane compounds.

Examples of the isocyanate compound include phenylene diisocyanate, toluylene diisocyanate, xylylene diisocyanate, hexamethylene diisocyanate, isophorone diisocyanate, cyclohexane diisocyanate, trimethyl phenylene diisocyanate, diphenyl methane diisocyanate, dicyclohexylmethane diisocyanate and tetramethyl xylylene diisocyanate. Isophorone diisocyanate is preferred because control of reaction is easy. A block isocyanate compound with an isocyanate group blocked with an amine may be used.

The alkoxy compound refers to a compound having in a molecule an alkoxy group which is condensed while generating an alcohol when heated. Examples of the alkoxy group include a methoxy group, an ethoxy group, a butoxy group and an isobutoxy group. Examples of the alkoxy compound include N-methoxymethyl acrylamide; N-ethoxymethyl acrylamide; N-n-butoxymethyl acrylamide; N-isobutoxymethyl acrylamide; butoxyethyl acrylate; butoxytriethylene glycol acrylate; HMOM-TPHAP (manufactured by Honshu Chemical Industry Co., Ltd.); MW-30M, MW-30, MW-22, MS-11, MS-001, MX-730, MX-750, MX-706, MX-035, BL-60, BX-37, MX-302, MX-45, MX-410, BX-4000 and BX-37 (each manufactured by SANWA CHEMICAL CO., LTD.); and NIKALAC (registered trademark) MW-30HM, NIKALAC (registered trademark) MW-390, NIKALAC (registered trademark) MX-270, NIKALAC (registered trademark) MX-280, NIKALAC (registered trademark) MW-100LM and NIKALAC (registered trademark) MX-750LM (each manufactured by SANWA CHEMICAL CO., LTD.).

Preferably, the conductive paste contains a photopolymerization initiator (D) as necessary. The photopolymerization initiator (D) refers to a compound which is decomposed by absorbing light having a short wavelength such as an ultraviolet ray, or which causes a hydrogen extraction reaction to generate a radical. Examples of the photopolymerization initiator (D) include 2-(benzoyloxyimino)-1-[4-(phenyl thio)phenyl]-1-octanone, 2,4,6-trimethylbenzoyl-di-phenyl-phosphine oxide, bis(2,4,6-trimethylbenzoyl)-phenyl-phosphine oxide, 6-[1-(acetyloxy-imino)ethyl]-9-ethyl-9H-carbazole-3-yl(2-methylphenyl)ketone, benzophenone, methyl o-benzoylbenzoate, 4,4′-bis(dimethylamino)benzophenone, 4,4′-bis(diethylamino)benzophenone, 4,4′-dichlorobenzophenone, 4-benzoyl-4′-methyldiphenylketone, dibenzylketone, fluorenone, 2,2′-diethoxyacetophenone, 2,2-dimethoxy-2-phenylacetophenone, 2-hydroxy-2-methylpropiophenone, p-t-butyldichloroacetophenone, thioxanthone, 2-methylthioxanthone, 2-chlorothioxanthone, 2-isopropylthioxanthone, diethylthioxanthone, benzyl, benzyl dimethyl ketal, benzyl-β-methoxyethyl acetal, benzoin, benzoin methyl ether, benzoin butyl ether, anthraquinone, 2-t-butylanthraquinone, 2-amylanthraquinone, β-chloroanthraquinone, anthrone, benzanthrone, dibenzosuberone, methylene anthrone, 4-azidebenzalacetophenone, 2,6-bis(p-azidebenzylidene)cyclohexanone, 6-bis(p-azidebenzylidene)-4-methylcyclohexanone, 1-phenyl-1,2-butane-dione-2-(o-methoxycarbonyl)oxime, 1-phenyl-propanedione-2-(o-ethoxycarbonyl)oxime, 1-phenyl-propanedione-2-(o-benzoyl)oxime, 1,3-diphenyl-propanetrione-2-(o-ethoxycarbonyl)oxime, 1-phenyl-3-ethoxy-propanetrione-2-(o-benzoyl)oxime, Michler's ketone, 2-methyl-[4-(methylthio)phenyl]-2-morpholino-1-propanone, naphthalenesulfonyl chloride, 2-benzyl-2-dimethylamino-1-(4-morpholinophenyl)-1-butanone (e.g., IRGACURE (registered trademark) 369, quinolinesulfonyl chloride, N-phenylthioacridone, 4,4′-azobisisobutyronitrile, diphenyl disulfide, benzothiazole disulfide, triphenylphosphine, camphor quinone, 2,4-diethylthioxanthone, isopropylthioxanthone, carbon tetrabromide, tribromophenylsulfone, benzoyl peroxide, and combinations of a photo-reductive pigment such as eosin and methylene blue, and a reducing agent such as ascorbic acid and triethanolamine.

The added amount of the photopolymerization initiator (D) is preferably not less than 0.05 parts by weight and not more than 100 parts by weight, more preferably not less than 0.5 parts by weight and not more than 15 parts by weight based on 15 parts by weight of the compound (C). When the added amount of the photopolymerization initiator (D) is 0.05 parts by weight or more based on 15 parts by weight of the compound (C), the curing density of an exposed part of the conductive paste increases so that the residual film ratio after developing increases. On the other hand, when the added amount of the photopolymerization initiator (D) is 100 parts by weight or less based on 15 parts by weight of the compound (C), excessive absorption of light at the upper part of a coating film obtained by applying the conductive paste is suppressed. As a result, the produced conductive pattern is inhibited from being reversely tapered to reduce adhesion to the substrate.

The conductive paste may contain a sensitizer along with the photopolymerization initiator (D).

Examples of the sensitizer include 2,4-diethylthioxanthone, isopropylthioxanthone, 2,3-bis(4-diethylaminobenzal)cyclopentanone, 2,6-bis(4-dimethylaminobenzal)cyclohexanone, 2,6-bis(4-dimethylaminobenzal)-4-methylcyclohexanone, Michler's ketone, 4,4-bis(diethylamino)benzophenone, 4,4-bis(dimethylamino)chalcone, 4,4-bis(diethylamino)chalcone, p-dimethyl-aminocinnamylideneindanone, p-dimethylaminobenzylideneindanone, 2-(p-dimethylaminophenylvinylene)isonaphthothiazole, 1,3-bis(4-dimethylaminophenylvinylene)isonaphthothiazole, 1,3-bis(4-dimethylaminobenzal)acetone, 1,3-carbonylbis(4-diethylaminobenzal)acetone, 3,3-carbonylbis(7-diethylaminocoumarin), N-phenyl-N-ethylethanolamine, N-phenylethanolamine, N-tolyldiethanolamine, isoamyl dimethylaminobenzoate, isoamyl diethylaminobenzoate, 3-phenyl-5-benzoylthiotetrazole, and 1-phenyl-5-ethoxycarbonylthiotetrazole.

The added amount of the sensitizer is preferably not less than 0.05 parts by weight and not more than 30 parts by weight, more preferably not less than 0.1 parts by weight and not more than 8 parts by weight based on 15 parts by weight of the compound (C). When the added amount of the sensitizer is 0.05 parts by weight or more based on 15 parts by weight of the compound (C), the exposure sensitivity is sufficiently improved. On the other hand, when the added amount of the sensitizer is 30 parts by weight or less based on 15 parts by weight of the compound (C), excessive absorption of light at the upper part of a coating film obtained by applying the conductive paste is suppressed. As a result, the produced conductive pattern is inhibited from being reversely tapered to reduce adhesion to the substrate.

Preferably, the conductive paste contains a compound (E) having a carboxyl group (hereinafter, referred to as “compound E”) as necessary. The compound (E) refers to a monomer, oligomer or polymer having at least one carboxyl group.

Examples of the compound (E) include acryl-based copolymers. The acryl-based copolymer refers to a copolymer containing as a copolymerization component an acryl-based monomer having a carbon-carbon double bond. When the conductive paste is to be made photosensitive, it is preferred that the compound (E) has a carbon-carbon double bond because the reaction rate of a curing reaction caused by exposure can be increased. By including the photopolymerization initiator (D) together with the compound (E) having a carbon-carbon double bond, photosensitivity can be imparted to the conductive paste. The photosensitivity refers to such a nature that when an applied and dried coating film is irradiated with an active ray, a reaction such as photo-crosslinking, photopolymerization, photodepolymerization or photomodification occurs to change the chemical structure of the irradiated part, thus making it possible to perform development with a developer.

Examples of the acryl-based monomer having a carbon-carbon double bond include acryl-based monomers such as methyl acrylate, acrylic acid, 2-ethylhexyl acrylate, ethyl acrylate, n-butyl acrylate, iso-butyl acrylate, iso-propane acrylate, glycidyl acrylate, N-methoxymethyl acrylamide, N-ethoxymethyl acrylamide, N-n-butoxymethyl acrylamide, N-isobutoxymethyl acrylamide, butoxytriethylene glycol acrylate, dicyclopentanyl acrylate, dicyclopentenyl acrylate, 2-hydroxyethyl acrylate, isobonyl acrylate, 2-hydroxypropyl acrylate, isodexyl acrylate, isooctyl acrylate, lauryl acrylate, 2-methoxyethyl acrylate, methoxyethylene glycol acrylate, methoxydiethylene glycol acrylate, octafluoropentyl acrylate, phenoxyethyl acrylate, stearyl acrylate, trifluoroethyl acrylate, acrylamide, aminoethyl acrylate, phenyl acrylate, phenoxyethyl acrylate, 1-naphthyl acrylate, 2-naphthyl acrylate, thiophenol acrylate, benzyl mercaptan acrylate, allylated cyclohexyl diacrylate, 1,4-butanediol diacrylate, 1,3-butylene glycol diacrylate, ethylene glycol diacrylate, diethylene glycol diacrylate, triethylene glycol diacrylate, polyethylene glycol diacrylate, dipentaerythritol hexaacrylate, dipentaerythritol monohydroxypentaacrylate, ditrimethylolpropane tetraacrylate, glycerol diacrylate, methoxylated cyclohexyl diacrylate, neopentyl glycol diacrylate, propylene glycol diacrylate, polypropylene glycol diacrylate, triglycerol diacrylate, trimethylolpropane triacrylate.

Examples of the acryl-based monomer also include epoxy acrylates such as acrylic acid adducts of ethylene glycol diglycidyl ether, acrylic acid adducts of diethylene glycol diglycidyl ether, acrylic acid adducts of neopentyl glycol diglycidyl ether, acrylic acid adducts of glycerin diglycidyl ether, acrylic acid adducts of bisphenol A type epoxy resins, acrylic acid adducts of bisphenol F type epoxy resins and acrylic acid adducts of cresol novolac type epoxy resins, each having a hydroxyl group generated by ring-opening an epoxy group with an unsaturated acid.

Examples of the compound (E) include methacryl-based copolymers. The methacryl-based copolymer refers to a copolymer containing as a copolymerization component a methacryl-based monomer having a carbon-carbon double bond. Examples of the methacryl-based monomer include compounds with the acrylic group of the above-mentioned acryl-based monomer replaced by a methacrylic group. Hereinafter, the methacryl-based copolymer may also be referred to as an acryl-based copolymer.

To form a conductive pattern having a further excellent hardness, an acryl-based copolymer containing an epoxy acrylate or epoxy methacrylate as an acryl-based monomer having a carbon-carbon double bond is preferred, and an acryl-based copolymer containing an epoxy acrylate or epoxy methacrylate with a polyfunctional isocyanate addition-reacted with a hydroxyl group is more preferred.

An alkali-soluble acryl-based copolymer having a carboxyl group is obtained by using as a monomer an unsaturated acid such as an unsaturated carboxylic acid. Examples of the unsaturated acid include acrylic acid, methacrylic acid, itaconic acid, crotonic acid, maleic acid, fumaric acid and vinylacetic acid, or acid anhydrides thereof. The acid value of the resulting acryl-based copolymer can be adjusted by increasing or reducing the amount of an unsaturated acid to be used.

The “acryl-based copolymer containing an epoxy acrylate or epoxy methacrylate with a polyfunctional isocyanate addition-reacted with a hydroxyl group” is obtained by reacting an epoxy acrylate or epoxy methacrylate with a polyfunctional isocyanate and a polyhydric alcohol having a carboxyl group.

When the carboxyl group of the acryl-based copolymer is reacted with a compound having an unsaturated double bond such as glycidyl (meth)acrylate, an alkali-soluble acryl-based copolymer having a reactive unsaturated double bond on the side chain is obtained.

Examples of other copolymer components contained in the acryl-based copolymer include styrenes such as styrene, p-methylstyrene, o-methylstyrene, m-methylstyrene, α-methylstyrene, chloromethylstyrene and hydroxymethylstyrene; γ-methacryloxypropyltrimethoxysilane; and 1-vinyl-2-pyrrolidone.

The acid value of the compound (E) is preferably 40 to 250 mg KOH/g, more preferably 50 to 200 mg KOH/g for achieving optimum alkali solubility of the compound (E). When the acid value is 40 mg KOH/g or more, the solubility of the soluble moiety is improved. On the other hand, when the acid value is 250 mg KOH/g or less, the development allowable range becomes wide. The acid value of the compound (E) can be measured in accordance with JIS K 0070 (1992).

The added amount of the compound (E) is preferably not less than 5 parts by weight and not more than 150 parts by weight, more preferably not less than 15 parts by weight and not more than 80 parts by weight based on 15 parts by weight of the compound (C). When the added amount of the compound (E) is 5 parts by weight or more based on 15 parts by weight of the compound (C), developability is improved. When the added amount of the compound (E) is 150 parts by weight or less based on 15 parts by weight of the compound (C), the content of the compound (C) becomes relatively high so that adhesion is improved.

Preferably, the conductive paste contains a compound (F) having a carbon-carbon double bond (hereinafter, referred to as “compound F”) as necessary. By including the photopolymerization initiator (D) and the compound (F), photocurability can be imparted to the conductive paste. By including the photopolymerization initiator (D), the compound (E) and the compound (F), photosensitivity can be imparted to the conductive paste. When the compound (E) has a carbon-carbon double bond in addition to a carboxyl group, the necessity to include the compound (F) may be lessened because the compound (E) itself has photocurability. Even when the compound (E) has a carbon-carbon double bond in addition to a carboxyl group, the compound (E) is not encompassed in the compound (F).

Examples of the compound (F) include various kinds of acrylic acid esters such as methyl acrylate, ethyl acrylate, n-propyl acrylate, isopropyl acrylate, n-butyl acrylate, sec-butyl acrylate, isobutyl acrylate, tert-butyl acrylate, n-pentyl acrylate, ally acrylate, benzyl acrylate, butoxyethyl acrylate, butoxytriethylene glycol acrylate, cyclohexyl acrylate, dicyclopentanyl acrylate, dicyclopentenyl acrylate, 2-ethylhexyl acrylate, glycerol acrylate, glycidyl acrylate, heptadecafluorodecyl acrylate, 2-hydroxyethyl acrylate, isobornyl acrylate, 2-hydroxypropyl acrylate, isodecyl acrylate, isooctyl acrylate, lauryl acrylate, 2-methoxyethyl acrylate, methoxyethylene glycol acrylate, methoxydiethylene glycol acrylate, octafluoropentyl acrylate, phenoxyethyl acrylate, stearyl acrylate, trifluoroethyl acrylate, allylated cyclohexyl diacrylate, 1,4-butanediol diacrylate, 1,3-butylene glycol diacrylate, ethylene glycol diacrylate, diethylene glycol diacrylate, triethylene glycol diacrylate, polyethylene glycol diacrylate, dipentaerythritol hexaacrylate, dipentaerythritol monohydroxypentaacrylate, ditrimethylolpropane tetraacrylate, glycerol diacrylate, methoxylated cyclohexyl diacrylate, neopentyl glycol diacrylate, propylene glycol diacrylate, polypropylene glycol diacrylate, triglycerol diacrylate, trimethylolpropane triacrylate, acrylamide, aminoethyl acrylate, phenyl acrylate, phenoxyethyl acrylate, benzyl acrylate, 1-naphthyl acrylate, 2-naphthyl acrylate, bisphenol A diacrylate, diacrylates of bisphenol A-ethylene oxide adducts, diacrylates of bisphenol A-propylene oxide adducts, epoxy acrylates and urethane acrylates; thiophenol acrylate and benzylmercaptan acrylate, or monomers in which one to five of hydrogen atoms of the aromatic ring of these monomers are replaced by chlorine or bromine atoms; and styrene, p-methylstyrene, o-methylstyrene, m-methylstyrene, chlorinated styrene, brominated styrene, α-methylstyrene, chlorinated α-methylstyrene, brominated α-methylstyrene, chloromethylstyrene, hydroxymethylstyrene, carboxymethylstyrene, vinyl naphthalene, vinyl anthracene and vinyl carbazole.

Examples of the compound (F) also include compounds with some or all of acrylate groups replaced by methacrylate groups in the molecule of the above-mentioned compound having a carbon-carbon double bond. In polyfunctional monomers, acrylic groups, methacrylic groups, vinyl groups and ally groups may coexist. For forming a conductive pattern having a further excellent hardness, epoxy acrylates and epoxy methacrylates are preferred.

The conductive paste may contain a solvent. Examples of the solvent include N,N-dimethylacetamide, N,N-dimethylformamide, N-methyl-2-pyrrolidone, dimethyl imidazolidinone, dimethyl sulfoxide, diethylene glycol monoethyl ether, diethylene glycol monoethyl ether acetate (hereinafter, referred to as “CA”), diethylene glycol monomethyl ether acetate, diethylene glycol monobutyl ether, diethylene glycol monobutyl ether acetate, γ-butyrolactone, ethyl lactate, 1-methoxy-2-propanol, 1-ethoxy-2-propanol, ethylene glycol mono-n-propyl ether, diacetone alcohol, tetrahydrofurfuryl alcohol and propylene glycol monomethyl ether acetate.

The added amount of the compound (F) is preferably not less than 0.3 parts by weight and not more than 90 parts by weight, more preferably not less than 3 parts by weight and not more than 30 parts by weight based on 15 parts by weight of the compound (C). When the added amount of the compound (F) is 0.3 parts by weight or more based on 15 parts by weight of the compound (C), the development resistance of the exposed part is improved. When the added amount of the compound (F) is 90 parts by weight or less based on 15 parts by weight of the compound (C), the content of the compound (C) becomes relatively high so that adhesion is improved.

The conductive paste may contain additives such as a non-photosensitive polymer having no unsaturated double bond in the molecule, or a plasticizer, a leveling agent, a surfactant, a silane coupling agent, a curing agent/curing accelerator, an antifoaming agent and a pigment as long as the desired characteristics of the conductive paste are not impaired.

Examples of the non-photosensitive polymer include cellulose compounds such as methyl cellulose and ethyl cellulose, and high-molecular-weight polyethers.

Examples of the plasticizer include dibutyl phthalate, dioctyl phthalate, polyethylene glycol, and glycerin.

Examples of the leveling agent include special vinyl-based polymers and special acryl-based polymers.

Examples of the silane coupling agent include methyltrimethoxysilane, dimethyldi-ethoxysilane, phenyltriethoxysilane, hexamethyldisilazane, 3-methacryloxypropyltrimethoxysilane, 3-glycidoxypropyltrimethoxysilane, and vinyltrimethoxysilane.

Examples of the curing agent/curing accelerator include imidazole, and imidazole derivatives such as 2-methylimidazole, 2-ethylimidazole, 2-ethyl-4-methylimidazole, 2-phenylimidazole and 4-phenylimidazole; amine compounds such as dicyandiamide, benzyldimethylamine, 4-methoxy-N,N-dimethylbenzylamine and 4-methyl-N,N-dimethylbenzylamine; hydrazide compounds such as dihydrazide adipate and dihydrazide sebacate; and phosphorus compounds such as triphenylphosphine.

The conductive paste is produced using, for example, a disperser or a kneader such as a three-roll mill, a ball mill, and a planetary ball mill.

A method of producing a conductive pattern using the conductive paste will now be described.

The conductive pattern obtained by the method is a composite of an organic component and an inorganic component, and exhibits conductivity as conductive fillers (c) contained in the conductive paste come into contact with one another due to curing shrinkage during curing.

To produce a conductive pattern, first the conductive paste is applied onto a substrate to obtain a coating film, and the obtained coating film is dried to volatilize a solvent. Thereafter, the dried film is exposed via a pattern forming mask, and then developed to form a desired pattern on the substrate. The obtained pattern is then cured at not lower than 100° C. and not higher than 200° C. to obtain a conductive pattern. The curing temperature is more preferably not lower than 120° C. and not higher than 150° C. When the curing temperature is lower than 100° C., the volume shrinkage amount of the resin does not increase, and thus the resistivity cannot be reduced. On the other hand, when the heating temperature is higher than 200° C., a conductive pattern cannot be formed on a material such as a substrate which has low heat resistance. Specifically, the temperature in the low-temperature curing conditions is 200° C. or less.

Examples of the substrate include polyethylene terephthalate films (hereinafter, referred to as a “PET film”), polyimide films, polyester films, aramid films, epoxy resin substrates, polyether imide resin substrates, polyether ketone resin substrates, polysulfone-based resin substrates, glass substrates, silicon wafers, alumina substrates, aluminum nitride substrates, silicon carbide substrates, decorative layer-formed substrates and insulating layer-formed substrates.

Examples of the method of applying the conductive paste to the substrate include spin coating by a spinner, spray coating, roll coating, screen printing, and coating by a blade coater, a die coater, a calender coater, a meniscus coater, or a bar coater. The film thickness of the coating film obtained may be appropriately determined according to, for example, a coating method, or a total solid concentration or a viscosity of the conductive paste, but the film thickness after drying is preferably not less than 0.1 μm and not more than 50 μm. The film thickness can be measured using a probe type step profiler such as SURFCOM (registered trademark) 1400 (manufactured by TOKYO SEIMITSU CO., LTD.). More specifically, the film thickness is measured at randomly selected three positions using a probe type step profiler (measurement length: 1 mm; scanning speed: 0.3 mm/sec), and an average value thereof is defined as a film thickness.

Examples of the method of volatilizing and removing a solvent by drying the obtained coating film include heating/drying by an oven, a hot plate, an infrared ray or the like and vacuum drying. The heating temperature is preferably not lower than 50° C. and not higher than 150° C., and the heating time is preferably 1 minute to several hours.

The coating film is dried, and then exposed. For exposure of the coating film, a method is generally employed in which the coating film is exposed via a photomask, as in usual photolithography. A method may also be employed in which a pattern is drawn directly by laser light or the like without using a photomask. Examples of exposure equipment include a stepper exposure machine and a proximity exposure machine. Examples of the active light source to be used at this time include near-ultraviolet rays, ultraviolet rays, electron beams, X rays and laser light, with ultraviolet rays being preferred. Examples of the light source of ultraviolet rays include low-pressure mercury lamps, high-pressure mercury lamps, ultrahigh pressure mercury lamps, halogen lamps and bactericidal lamps, with ultrahigh pressure mercury lamps being preferred.

The exposed dried film is developed using a developer, and an unexposed part is dissolved and removed to obtain a desired pattern. Examples of the developer to be used for alkali development include aqueous solutions of tetramethylammonium hydroxide, diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, dimethylaminoethyl methacrylate, cyclohexylamine, ethylenediamine, and hexamethylenediamine. To these aqueous solutions may be added a polar solvent such as N-methyl-2-pyrrolidone, N,N-dimethylformamide, N,N-dimethylacetamide, dimethyl sulfoxide, and γ-butyrolactone, an alcohol such as methanol, ethanol, and isopropanol, an ester such as ethyl lactate and propylene glycol monomethyl ether acetate, a ketone such as cyclopentanone, cyclohexanone, isobutyl ketone, and methyl isobutyl ketone, or a surfactant.

Examples of the developer to be used for organic development include polar solvents such as N-methyl-2-pyrrolidone, N-acetyl-2-pyrrolidone, N,N-dimethylacetamide, N,N-dimethylformamide, dimethyl sulfoxide, and hexamethylphosphortriamide, and mixed solutions of these polar solvents and methanol, ethanol, isopropyl alcohol, xylene, water, methyl carbitol or ethyl carbitol.

Examples of the development method include a method in which a developer is sprayed on a coating film surface while a substrate is left at rest or rotated, a method in which a substrate is immersed in a developer, and a method in which a substrate is immersed in a developer while an ultrasonic wave is applied thereto.

The pattern obtained by development may be subjected to a rinsing treatment with a rinsing liquid. Examples of the rinsing liquid include water, and aqueous solutions obtained by adding to water an alcohol such as ethanol and isopropyl alcohol, or an ester such as ethyl lactate and propylene glycol monomethyl ether acetate.

Examples of the method of curing the obtained pattern include heating by an oven, an inert oven, a hot plate or the like, heating by an infrared ray, a microwave or the like, and heating by xenon flash lamp radiation.

A conductive pattern produced using the conductive paste is suitably used as peripheral wiring for a touch panel. Examples of the type of touch panel include a resistive film type, an optical type, an electromagnetic induction type, and an electrostatic capacitance type, and a conductive pattern produced using the conductive paste is more suitably used in the electrostatic capacitance type touch panel because this type of touch panel requires particularly fine wiring. In a touch panel including a conductive pattern produced using the conductive paste as peripheral wiring of the touch panel, the peripheral wiring having a pitch (wiring width+inter-wiring width) of preferably 50 μm or less, the frame width can be decreased to widen a view area.

### EXAMPLES

Hereinafter, my methods, pastes and touch panels will be described more in detail by way of Examples and Comparative Examples, but this disclosure is not limited to these examples.

Evaluation methods used in Examples and Comparative Examples are as follows.

### Method of Evaluating Patterning Characteristics

### Coating Step

The conductive paste was applied onto a PET film substrate such that the dried film had a film thickness of 7 μm.

### Drying Step

The obtained coating film was dried in a hot-air oven at 100° C. for 5 minutes.

### Pattern Forming Step

The dried film was exposed via a photomask having nine units having different L/S values, with one unit including a group of lines arranged with a fixed line width/space (hereinafter, referred to as L/S), namely a light transmission pattern, and developed to obtain nine patterns having different L/S values.

### Curing Step

Thereafter, the obtained nine patterns were each cured in a hot-air oven at 130° C. for 60 minutes to obtain nine conductive patterns having different L/S values.

The L/S values of the units of the photomask were set to 500/500, 250/250, 100/100, 50/50, 40/40, 30/30, 25/25, 20/20 and 15/15 (each showing a line width (μm)/interval (μm)). The obtained conductive patterns were observed with an optical microscope to confirm a pattern which was free from residues between patterns and free from pattern peeling and had the smallest L/S value, and the L/S value was defined as a development-enabling L/S value. Exposure was performed over the entire line at an exposure amount of 150 mJ/cm² (in terms of a wavelength of 365 nm) using exposure equipment (PEM-6M manufactured by UNION OPTICAL CO., LTD.), and development was performed by immersing a substrate in a 0.2 wt % aqueous Na₂CO₃ solution for 30 seconds, and then subjecting the substrate to a rinsing treatment with ultrapure water.

### Method of Evaluating Resistivity

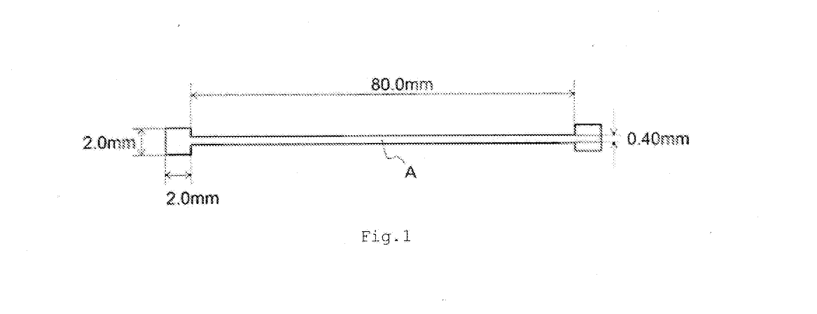

The conductive paste was applied onto a PET film such that the dried film had a film thickness of 7 μm, and the obtained coating film was dried in a hot-air oven at 100° C. for 5 minutes. The coating film after drying was exposed through a photomask having a light transmission part A with a pattern as shown in FIG. 1, and was developed to obtain a pattern. Thereafter, the obtained pattern was cured in a hot-air oven at 130° C. for 60 minutes to obtain a conductive pattern for measurement of a resistivity. The obtained conductive pattern had a line width of 0.400 mm and a line length of 80 mm.

Conditions for exposure and development were the same as those in the method of evaluating patterning characteristics. To each of the ends of the obtained conductive pattern for measurement of a resistivity, an ohmmeter was connected to measure a resistance value, and a resistivity was calculated based on Formula (1):

Resistivity=resistance value×film thickness×line width/line length (1).

The line width is an average value obtained by observing line widths at three random positions with an optical microscope, and analyzing image data.
Method of Evaluating Adhesion with ITO

The conductive paste was applied onto a PET film with ITO “ELECRYSTA” (registered trademark) V270L-TFS (manufactured by NITTO DENKO CORPORATION) such that the dried film had a film thickness of 7 μm, and the obtained coating film was dried in a hot-air oven at 100° C. for 5 minutes, then exposed over the entire surface thereof, and then exposed. Conditions for exposure and development were the same as those in the method of evaluating patterning characteristics. Thereafter, the obtained film was cured in a hot-air oven at 130° C. for 60 minutes, a cut was then made in the form of 10×10 squares with a width of 1 mm, and the film was placed in a thermo-hygrostat bath SH-661 (manufactured by ESPEC Corp.) at 85° C. and 85% RH for 240 hours. A cellophane tape (manufactured by NICHIBAN CO., LTD.) was attached at the entire location of the squares of the sample taken out from the bath, and peeled off, and the number of remaining squares was counted.

### Pencil Hardness

The conductive paste was applied onto a PET film such that the dried film had a film thickness of 7 μm, and the obtained coating film was dried in a hot-air oven at 100° C. for 5 minutes, then exposed over the entire surface, and then developed. Conditions for exposure and development were the same as those in the method of evaluating patterning characteristics. Thereafter, the obtained film was cured in a hot-air oven at 130° C. for 60 minutes, followed by measuring the pencil hardness in accordance with the test method in JIS K5600-5-6. The pencil hardness is defined by 22 grades: 10B, 9B, 8B, 7B, 6B, 5B, 4B, 3B, 2B, B, HB, F, H, 2H, 3H, 4H, 5H, 6H, 7H, 8H, 9H and 10H in the ascending order. The pencil hardness was indicated by the maximum hardness that did not cause the film coating to be scratched when a load of 1 kg was applied using a pencil hardness tester. Mitsubishi Hi-uni (manufactured by MITSUBISHI PENCIL CO., LTD.) was used as a pencil.

Materials used in Examples and Comparative Examples are as follows.

### Conductive Filler (A)

Ag particles having a median diameter (D50) of 1 μm (D50 was measured using Microtrac HRA Model No. 9320-X100 manufactured by NIKKISO CO., LTD.).

### Zwitterionic Compound (B)

L-alanine (effective component: 100% by weight; manufactured by Tokyo Chemical Industry Co., Ltd.)
L-leucine (effective component: 100% by weight; manufactured by Tokyo Chemical Industry Co., Ltd.)
L-phenylalanine (effective component: 100% by weight; manufactured by Tokyo Chemical Industry Co., Ltd.)
N,N,N-trimethylglycine (effective component: 100% by weight; manufactured by Wako Pure Chemical Industries, Ltd.)
L-carnitine (effective component: 100% by weight; manufactured by Wako Pure Chemical Industries, Ltd.)
YUKAFORMER (registered trademark) AMPHOSET (effective component: 50% by weight; manufactured by Mitsubishi Chemical Corporation)
YUKAFORMER (registered trademark) SM (effective component: 30% by weight; manufactured by Mitsubishi Chemical Corporation)
AMPHITOL 24B (effective component: 26% by weight; manufactured by Kao Corporation)
AMPHITOL 20YB (effective component: 40% by weight; manufactured by Kao Corporation)

### Thermosetting Compound (C)

Compound (C-1): jER (registered trademark) 828 (containing an epoxy group, epoxy equivalent: 188; manufactured by Mitsubishi Chemical Corporation)
Compound (C-2): ADEKA RESIN EPR-21 (containing an epoxy group, epoxy equivalent: 210; manufactured by ADEKA CORPORATION)
Compound (C-3): ADEKA RESIN EPR-4030 (containing an epoxy group, epoxy equivalent: 380; manufactured by ADEKA CORPORATION)
Compound (C-4): jER (registered trademark) 1001 (containing an epoxy group, epoxy equivalent: 475; manufactured by Mitsubishi Chemical Corporation)
Compound (C-5): jER (registered trademark) 1002 (containing an epoxy group, epoxy equivalent: 650; manufactured by Mitsubishi Chemical Corporation)
Compound (C-6): jER (registered trademark) 1256 (containing an epoxy group, epoxy equivalent: 8000; manufactured by Mitsubishi Chemical Corporation)
Compound (C-7): ARON OXETANE (registered trademark) OXT-101 (containing an oxetane group; manufactured by Toagosei Company, Limited)

### Photopolymerization Initiator (D)

IRGACURE (registered trademark) 369 (manufactured by BASF Ltd.)

### Compound (E) Having a Carboxyl Group

### Synthesis Example 1

Epoxy Ester 3000A (200 g) (manufactured by KYOEISHA CHEMICAL Co., LTD.; epoxy acrylate compound having a bisphenol A backbone), 260 g of CA, 0.5 g of 2-methylhydroquinone (thermal polymerization inhibitor) and 125 g of 2,2-bis(hydroxymethyl)propionic acid were added in a reaction vessel, and heated to 45° C. using an oil bath. To this was gradually added dropwise 150 g of hexamethylene diisocyanate such that the reaction temperature did not exceed 50° C. After completion of the dropwise addition, the reaction temperature was elevated to 80° C., and after 6 hours, the reaction solution was analyzed by infrared absorption spectrometry. The result showed that there was no absorption around 2250 cm⁻¹. To this reaction solution were added 22 g of glycidyl methacrylate, 10 g of CA, 0.4 g of 2-methylhydroquinone and 1.5 g of triphenylphosphine (reaction catalyst), the mixture was then heated to 95° C., and reacted for 6 hours to obtain a compound (E-1) having a solid content ratio of 64.9% by weight. The obtained compound (E-1) had an acid value (solid content) of 87 mg KOH/g and a weight average molecular weight of 12000.

### Synthesis Example 2

CA (150 g) was added in a reaction vessel in a nitrogen atmosphere, and the temperature was elevated to 80° C. using an oil bath. To this was added dropwise for 1 hour a mixture including 20 g of ethyl acrylate, 40 g of 2-ethylhexyl methacrylate, 20 g of styrene, 15 g of acrylic acid, 0.8 g of 2,2′-azobisisobutyronitrile and 10 g of CA. After completion of the dropwise addition, further a polymerization reaction was carried out for 6 hours. Thereafter, 1 g of hydroquinone monomethyl ether was added to stop the polymerization reaction. Subsequently, a mixture including 5 g of glycidyl methacrylate, 1 g of triethyl benzyl ammonium chloride and 10 g of CA was added dropwise for 0.5 hours. After completion of the dropwise addition, further an addition reaction was carried out for 2 hours. The obtained reaction solution was refined with methanol to remove unreacted impurities, and dried under vacuum for 24 hours to obtain a compound (E-2) having a carboxyl group. The obtained compound (E-2) had an acid value of 97 mg KOH/g and a weight average molecular weight of 16000.

### Compound (F) Having a Carbon-Carbon Double Bond

LIGHT ACRYLATE BP-4EA (manufactured by KYOEISHA CHEMICAL Co., LTD)

### Solvent

Diethylene glycol monoethyl ether acetate (CA: manufactured by Tokyo Chemical Industry Co., Ltd.)

### Example 1

L-leucine (0.186 g) as the zwitterionic compound (B), 1.5 g of the epoxy compound (C-3) as the thermosetting compound (C), 7.7 g of the compound (E-1) (solid content: 5.0 g, CA: 2.7 g) as the compound (E) having a carboxyl group, 0.5 g of IRGACURE (registered trademark) 369 as the photopolymerization initiator (D), 2.3 g of CA as a solvent and 1.0 g of BP-4EA as the compound (F) having a carbon-carbon double bond were added in a 100 mL clean bottle, and mixed by a rotating and revolving mixer “Awatori Rentaro” (registered trademark) (ARE-310 manufactured by THINKY CORPORATION) to obtain 13.186 g of a resin solution (solid content: 62.1% by weight).

The obtained resin solution (13.186 g) and 46.385 g of Ag particles as the conductive filler (A) were mixed together, and the mixture was kneaded using a three-roll roller (EXAKT M-50 manufactured by EXAKT) to obtain 59.571 g of a conductive paste.

The obtained conductive paste was used to prepare a conductive pattern, and the conductive pattern was evaluated for patterning characteristics, the resistivity, adhesion with ITO and the pencil hardness. The conductive pattern had a development-enabling L/S value, which was the evaluation index of patterning characteristics, of 15/15, and it was thus confirmed that proper pattern processing was performed. The resistivity of the conductive pattern was 58 μΩcm. The number of remaining squares was 100. The pencil hardness was 2H.

### Examples 2 to 14 and Examples 17 to 23

Conductive pastes having compositions as shown in Table 1 and Table 2 were produced in the same manner as in Example 1. Results of performing evaluations in the same manner as in Example 1 are shown in Table 3.

### Example 15

The epoxy compound (C-2) (1.5 g) as the thermosetting compound (C), 7.7 g of the compound (E-1) (solid content: 5.0 g, CA: 2.7 g) as the compound (E) having a carboxyl group, 0.5 g of IRGACURE (registered trademark) 369 as the photopolymerization initiator (D), 2.3 g of CA as a solvent and 1.0 g of BP-4EA as the compound (F) having a carbon-carbon double bond were added in a 100 mL clean bottle, and mixed by a rotating and revolving mixer “Awatori Rentaro” (registered trademark) (ARE-310 manufactured by THINKY CORPORATION) to obtain 13.0 g of a resin solution (solid content: 61.5% by weight).

On the other hand, 93.86 g of Ag particles as the conductive filler (A) and 2.8 g of a 10 wt % aqueous L-alanine solution (L-alanine: 0.28 g) as the zwitterionic compound (B) were added in an electrically-driven coffee mill (MJ-518; Melitta Japan Ltd.), and mixed and crushed for 10 seconds. Further, 2.8 g of a 10 wt % aqueous L-alanine solution (L-alanine: 0.28 g) was added, and the mixture was mixed and crushed for 20 seconds. The Ag particles subjected to the crushing treatment were taken out, and vacuum-dried at room temperature for 1 hour so that the solvent was removed to obtain Ag particles surface-treated with L-alanine.

The obtained resin solution (13.0 g) and 47.21 g of the Ag particles surface-treated with L-alanine were mixed together, and the mixture was kneaded using a three-roll roller (EXAKT M-50 manufactured by EXAKT) to obtain 60.21 g of a conductive paste.

The obtained conductive paste was used to prepare a conductive pattern, and the conductive pattern was evaluated for patterning characteristics, the resistivity, adhesion with ITO and the pencil hardness. The conductive pattern had a development-enabling L/S value, which was the evaluation index of patterning characteristics, of 15/15, and it was thus confirmed that proper pattern processing was performed. The resistivity of the conductive pattern was 55 μΩcm. The number of remaining squares was 100. The pencil hardness was 2H.

### Example 16

N,N,N-trimethylglycine (0.33 g) as the zwitterionic compound (B), 47.21 g of Ag particles as the conductive filler (A) and 2.3 g of CA as a solvent were added in a 100 mL clean bottle, and mixed by a rotating and revolving mixer “Awatori Rentaro” (registered trademark) (ARE-310 manufactured by THINKY CORPORATION). Thereafter, 1.5 g of the epoxy compound (C-2) as the thermosetting compound (C), 7.7 g of the compound (E-1) (solid content: 5.0 g, CA: 2.7 g) as the compound (E) having a carboxyl group, 0.5 g of IRGACURE (registered trademark) 369 as the photopolymerization initiator (D), and 1.0 g of BP-4EA as the compound (F) having a carbon-carbon double bond were added, and the mixture was mixed by a rotating and revolving mixer “Awatori Rentaro” (registered trademark) (ARE-310 manufactured by THINKY CORPORATION). Thereafter, the mixture was kneaded using a three-roll roller (EXAKT M-50 manufactured by EXAKT) to obtain 60.54 g of a conductive paste.

The obtained conductive paste was used to prepare a conductive pattern, and the conductive pattern was evaluated for patterning characteristics, the resistivity, adhesion with ITO and the pencil hardness. The conductive pattern had a development-enabling L/S value, which was the evaluation index of patterning characteristics, of 15/15, and it was thus confirmed that proper pattern processing was performed. The resistivity of the conductive pattern was 49 μΩcm. The number of remaining squares was 100. The pencil hardness was 2H.

### Comparative Examples 1 to 4

Conductive pastes having compositions as shown in Table 2 were produced in the same manner as in Example 1. Results of performing evaluations in the same manner as in Example 1 are shown in Table 3.

For the conductive paste of each of Examples 1 to 23, a conductive pattern excellent in patterning characteristics, resistivity, adhesion with ITO and pencil hardness was formed. The conductive pattern formed using the conductive paste of Comparative Example 1 had a high resistivity. The conductive patterns formed using the conductive pastes of Comparative Examples 2 to 4 had reduced adhesion with ITO at a high temperature and high humidity. Further, the hardness was insufficient.

TABLE 1

| | | | | | | Photopoly- |
|---|---|---|---|---|---|---|
| | Conductive | Zwitterionic | | Thermosetting | | merization |
| | filler (A) | compound (B) | | compound (C) | | Initiator (D) |
| | Ratio to total | | Ratio to | | Added | Added |
| | solid content | | conductive | | amount | amount |
| | in paste (% | | filler (% | | (parts by | (parts by |
| | by weight) | Type | by weight) | Type | weight) | weight) |
| Example 1 | 85 | L-leucine | 0.4 | C-3 | 15 | 5 |
| Example 2 | 85 | L-phenylalanine | 0.6 | C-2 | 15 | 5 |
| Example 3 | 85 | N,N,N-trimethyl | 0.5 | C-2 | 15 | 5 |
| | | Glycine | | | | |
| Example 4 | 85 | L-carnitine | 0.7 | C-4 | 15 | 5 |
| Example 5 | 85 | YUKAFORMER | 0.7 | C-2 | 15 | 5 |
| | | AMPHOSET | | | | |
| Example 6 | 85 | YUKAFORMER SM | 0.4 | C-3 | 15 | 5 |
| Example 7 | 85 | AMPHITOL 24B | 0.5 | C-4 | 15 | 5 |
| Example 8 | 85 | AMPHITOL 20YB | 0.5 | C-2 | 15 | 5 |
| Example 9 | 85 | L-phenylalanine | 0.3 | C-1 | 15 | 5 |
| Example 10 | 85 | N,N,N-trimethyl | 0.8 | C-5 | 15 | 5 |
| | | Glycine | | | | |
| Example 11 | 85 | L-leucine | 0.2 | C-6 | 15 | 5 |
| Example 12 | 85 | L-carnitine | 0.9 | C-7 | 15 | 5 |
| Example 13 | 85 | L-phenylalanine | 0.8 | C-2 | 15 | 5 |
| Example 14 | 85 | N,N,N-trimethyl | 2.0 | C-3 | 15 | 5 |
| | | Glycine | | | | |

| | Compound having | | Compound having carbon- | | | |
|---|---|---|---|---|---|---|
| | carboxyl group (E) | | carbon double bond (F) | | Solvent | |
| | | Solid content | | Added | | Added |
| | | added amount | | amount | | amount |
| | | (parts by | | (parts by | | (parts by |
| | Type | weight) | Type | weight) | Type | weight) |
| Example 1 | E-1 | 50 | BP-4EA | 10 | CA | 50 |
| Example 2 | E-1 | 50 | BP-4EA | 10 | CA | 50 |
| Example 3 | E-1 | 50 | BP-4EA | 10 | CA | 50 |
| Example 4 | E-1 | 50 | BP-4EA | 10 | CA | 50 |
| Example 5 | E-1 | 50 | BP-4EA | 10 | CA | 50 |
| Example 6 | E-1 | 50 | BP-4EA | 10 | CA | 50 |
| Example 7 | E-1 | 50 | BP-4EA | 10 | CA | 50 |
| Example 8 | E-1 | 50 | BP-4EA | 10 | CA | 50 |
| Example 9 | E-1 | 50 | BP-4EA | 10 | CA | 50 |
| Example 10 | E-1 | 50 | BP-4EA | 10 | CA | 50 |
| Example 11 | E-1 | 50 | BP-4EA | 10 | CA | 50 |
| Example 12 | E-1 | 50 | BP-4EA | 10 | CA | 50 |
| Example 13 | E-2 | 50 | BP-4EA | 10 | CA | 50 |
| Example 14 | E-2 | 50 | BP-4EA | 10 | CA | 50 |

TABLE 2

| | | | | | | Photopoly- |
|---|---|---|---|---|---|---|
| | Conductive | Zwitterionic | | Thermosetting | | merization |
| | filler (A) | compound (B) | | compound (C) | | Initiator (D) |
| | Ratio to total | | Ratio to | | Added | Added |
| | solid content | | Conductive | | amount | Amount |
| | in paste (% | | filler (% | | (parts by | (parts by |
| | by weight) | Type | by weight) | Type | weight) | weight) |
| Example 15 | 85 | L-alanine | 0.6 | C-2 | 15 | 5 |
| Example 16 | 85 | N,N,N-trimethyl | 0.7 | C-2 | 15 | 5 |
| | | glycine | | | | |
| Example 17 | 95 | L-carnitine | 1.0 | C-3 | 15 | 5 |
| Example 18 | 96 | L-carnitine | 1.0 | C-3 | 15 | 5 |
| Example 19 | 85 | N,N,N-trimethyl | 0.1 | C-4 | 15 | 5 |
| | | glycine | | | | |
| Example 20 | 85 | L-alanine | 4.5 | C-3 | 15 | 5 |
| Example 21 | 85 | L-leucine | 0.04 | C-3 | 15 | 5 |
| Example 22 | 85 | L-carnitine | 6.0 | C-4 | 15 | 5 |
| Example 23 | 85 | N,N,N-trimethyl | 7.0 | C-3 | 15 | 5 |
| | | glycine | | | | |
| Comparative | 85 | — | — | C-2 | 15 | 5 |
| Example 1 | | | | | | |
| Comparative | 85 | L-phenylalanine | 2.0 | — | — | 5 |
| Example 2 | | | | | | |
| Comparative | 85 | L-carnitine | 4.5 | — | — | 5 |
| Example 3 | | | | | | |
| Comparative | 85 | YUKAFORMER | 0.5 | — | — | 5 |
| Example 4 | | AMPHOSET | | | | |

| | Compound having | | Compound having carbon- | | | |
|---|---|---|---|---|---|---|
| | carboxyl group (E) | | carbon double bond (F) | | Solvent | |
| | | Solid content | | Added | | Added |
| | | added amount | | amount | | amount |
| | | (parts by | | (parts by | | (parts by |
| | Type | weight) | Type | weight) | Type | weight) |
| Example 15 | E-1 | 50 | BP-4EA | 10 | CA | 50 |
| Example 16 | E-1 | 50 | BP-4EA | 10 | CA | 50 |
| Example 17 | E-1 | 50 | BP-4EA | 10 | CA | 50 |
| Example 18 | E-1 | 50 | BP-4EA | 10 | CA | 50 |
| Example 19 | E-1 | 50 | BP-4EA | 10 | CA | 50 |
| Example 20 | E-1 | 50 | BP-4EA | 10 | CA | 50 |
| Example 21 | E-1 | 50 | BP-4EA | 10 | CA | 50 |
| Example 22 | E-1 | 50 | BP-4EA | 10 | CA | 50 |
| Example 23 | E-1 | 50 | BP-4EA | 10 | CA | 50 |
| Comparative | E-1 | 50 | BP-4EA | 10 | CA | 50 |
| Example 1 | | | | | | |
| Comparative | E-1 | 50 | BP-4EA | 10 | CA | 50 |
| Example 2 | | | | | | |
| Comparative | E-1 | 50 | BP-4EA | 10 | CA | 50 |
| Example 3 | | | | | | |
| Comparative | E-1 | 50 | BP-4EA | 10 | CA | 50 |
| Example 4 | | | | | | |

TABLE 3

| | Characteristic of conductive pattern | | | |
|---|---|---|---|---|
| | | | Adhesion with | |
| | | | ITO | |
| | Development- | | Number of | |
| | enabling L/S | Resistivity | remaining | Pencil |
| | (μm) | (μΩcm) | squares | hardness |
| Example 1 | 15/15 | 58 | 100 | 2H |
| Example 2 | 15/15 | 57 | 100 | 2H |
| Example 3 | 15/15 | 52 | 100 | 2H |
| Example 4 | 15/15 | 53 | 100 | 2H |
| Example 5 | 15/15 | 61 | 100 | 2H |
| Example 6 | 15/15 | 62 | 100 | 2H |
| Example 7 | 15/15 | 62 | 100 | 2H |
| Example 8 | 15/15 | 67 | 100 | 2H |
| Example 9 | 15/15 | 58 | 97 | 2H |
| Example 10 | 15/15 | 52 | 98 | 2H |
| Example 11 | 15/15 | 58 | 96 | 2H |
| Example 12 | 15/15 | 53 | 91 | 2H |
| Example 13 | 15/15 | 57 | 100 | H |
| Example 14 | 15/15 | 52 | 100 | H |
| Example 15 | 15/15 | 55 | 100 | 2H |
| Example 16 | 15/15 | 49 | 100 | 2H |
| Example 17 | 15/15 | 51 | 100 | 2H |
| Example 18 | 30/30 | 51 | 100 | 2H |
| Example 19 | 15/15 | 54 | 100 | 2H |
| Example 20 | 20/20 | 56 | 100 | 2H |
| Example 21 | 15/15 | 100 | 100 | 2H |
| Example 22 | 25/25 | 52 | 100 | 2H |
| Example 23 | 25/25 | 52 | 100 | 2H |
| Comparative | 15/15 | 1.0 × 10³ | 100 | 2H |
| Example 1 | | | | |
| Comparative | 15/15 | 57 | 30 | 2B |
| Example 2 | | | | |
| Comparative | 15/15 | 52 | 28 | 2B |
| Example 3 | | | | |
| Comparative | 15/15 | 62 | 32 | 2B |
| Example 4 | | | | |

### INDUSTRIAL APPLICABILITY

The conductive paste can be suitably used for producing a conductive pattern such as peripheral wiring for a touch panel.

1-8. (canceled)

9. A conductive paste comprising a conductive filler (A), a zwitterionic compound (B) and a thermosetting compound (C).

10. The conductive paste according to claim 9, wherein a ratio of the zwitterionic compound (B) to the conductive filler (A) is 0.05 to 5% by weight.

11. The conductive paste according to claim 9, further comprising a photopolymerization initiator (D), and a compound (E) having a carboxyl group and/or a compound (F) having a carbon-carbon double bond.

12. The conductive paste according to claim 11, wherein the compound (E) having a carboxyl group is an acryl-based copolymer containing an epoxy acrylate or an epoxy methacrylate as an acryl-based monomer having a carbon-carbon double bond.

13. The conductive paste according to claim 9, wherein the zwitterionic compound (B) is a compound selected from the group consisting of an amino acid, a compound represented by Formula (1) and a compound represented by Formula (2): 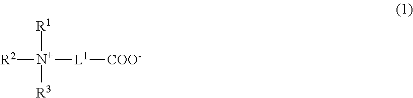
wherein R¹, R² and R³ each independently represent an organic group, and L¹ represents a divalent linking group, where R³ and R² or L¹ may be linked with each other to form a ring, and the ring may have a substituent; and 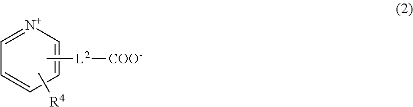
wherein R⁴ represents an alkyl group with a carbon number of 1 to 6 or a hydrogen atom, which is bonded at any one of the 1 to 6-positions of a pyridinium ring, and L² represents a divalent linking group bonded at any one of the 1 to 6-positions of the pyridinium ring, where R⁴ or L² is bonded at the 1-position of the pyridinium ring.

14. The conductive paste according to claim 13, wherein R¹, R² and R³ each independently represent an alkyl group with a carbon number of 1 to 6.

15. A method of producing a conductive pattern comprising:
applying the conductive paste according to claim 9 to obtain a coating film;
drying the coating film to obtain a dried film;
exposing and developing the dried film to obtain a pattern; and
curing the pattern at 100 to 200° C. to obtain a conductive pattern.

16. An electrostatic capacitance type touch panel comprising as peripheral wiring the conductive pattern produced by the method according to claim 15.

17. The conductive paste according to claim 10, further comprising a photopolymerization initiator (D), and a compound (E) having a carboxyl group and/or a compound (F) having a carbon-carbon double bond.

18. The conductive paste according to claim 10, wherein the zwitterionic compound (B) is a compound selected from the group consisting of an amino acid, a compound represented by Formula (1) and a compound represented by Formula (2): 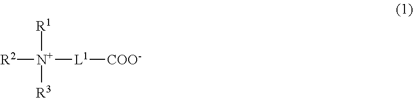
wherein R¹, R² and R³ each independently represent an organic group, and L¹ represents a divalent linking group, where R³ and R² or L¹ may be linked with each other to form a ring, and the ring may have a substituent; and 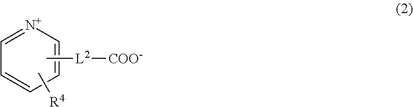
wherein R⁴ represents an alkyl group with a carbon number of 1 to 6 or a hydrogen atom, which is bonded at any one of the 1 to 6-positions of a pyridinium ring, and L² represents a divalent linking group bonded at any one of the 1 to 6-positions of the pyridinium ring, where R⁴ or L² is bonded at the 1-position of the pyridinium ring.

19. The conductive paste according to claim 11, wherein the zwitterionic compound (B) is a compound selected from the group consisting of an amino acid, a compound represented by Formula (1) and a compound represented by Formula (2): 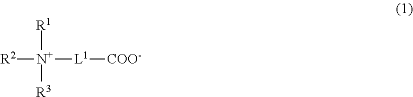
wherein R¹, R² and R³ each independently represent an organic group, and L¹ represents a divalent linking group, where R³ and R² or L¹ may be linked with each other to form a ring, and the ring may have a substituent; and 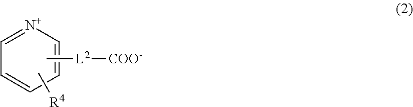
wherein R⁴ represents an alkyl group with a carbon number of 1 to 6 or a hydrogen atom, which is bonded at any one of the 1 to 6-positions of a pyridinium ring, and L² represents a divalent linking group bonded at any one of the 1 to 6-positions of the pyridinium ring, where R⁴ or L² is bonded at the 1-position of the pyridinium ring.

20. The conductive paste according to claim 12, wherein the zwitterionic compound (B) is a compound selected from the group consisting of an amino acid, a compound represented by Formula (1) and a compound represented by Formula (2): 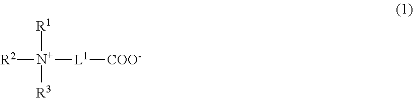
wherein R¹, R² and R³ each independently represent an organic group, and L¹ represents a divalent linking group, where R³ and R² or L¹ may be linked with each other to form a ring, and the ring may have a substituent; and 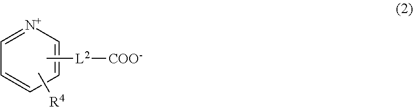
wherein R⁴ represents an alkyl group with a carbon number of 1 to 6 or a hydrogen atom, which is bonded at any one of the 1 to 6-positions of a pyridinium ring, and L² represents a divalent linking group bonded at any one of the 1 to 6-positions of the pyridinium ring, where R⁴ or L² is bonded at the 1-position of the pyridinium ring.

21. A method of producing a conductive pattern comprising:
applying the conductive paste according to claim 10 to obtain a coating film;
drying the coating film to obtain a dried film;
exposing and developing the dried film to obtain a pattern; and
curing the pattern at 100 to 200° C. to obtain a conductive pattern.

22. A method of producing a conductive pattern comprising:
applying the conductive paste according to claim 11 to obtain a coating film;
drying the coating film to obtain a dried film;
exposing and developing the dried film to obtain a pattern; and
curing the pattern at 100 to 200° C. to obtain a conductive pattern.

23. A method of producing a conductive pattern comprising:
applying the conductive paste according to claim 12 to obtain a coating film;
drying the coating film to obtain a dried film;
exposing and developing the dried film to obtain a pattern; and
curing the pattern at 100 to 200° C. to obtain a conductive pattern.

24. A method of producing a conductive pattern comprising:
applying the conductive paste according to claim 13 to obtain a coating film;
drying the coating film to obtain a dried film;
exposing and developing the dried film to obtain a pattern; and
curing the pattern at 100 to 200° C. to obtain a conductive pattern.

25. A method of producing a conductive pattern comprising:
applying the conductive paste according to claim 14 to obtain a coating film;
drying the coating film to obtain a dried film;
exposing and developing the dried film to obtain a pattern; and
curing the pattern at 100 to 200° C. to obtain a conductive pattern.
